(19) United States
(12) Patent Application Publication
(10) Pub. No.: US 2023/0216156 A1
(43) Pub. Date: Jul. 6, 2023

(54) Semiconductor Based Material for Battery Health and Performance Assessment and Monitoring in the Sub-Cell Level

(71) Applicant: SpinorX Inc., Toronto (CA)

(72) Inventors: Shahab Shokrzadeh, Aurora (CA); Pooneh Farhat, Aurora (CA)

(21) Appl. No.: 18/145,144

(22) Filed: Dec. 22, 2022

Related U.S. Application Data
(60) Provisional application No. 63/266,322, filed on Dec. 31, 2021.

(51) Int. Cl. H01M 50/569; G01R 31/392; G01R 31/382; H01M 4/04

(52) U.S. Cl. CPC H01M 50/569; G01R 31/392; G01R 31/382; H01M 4/0404

(57) ABSTRACT

The present invention comprises semiconductor materials for use in rechargeable energy storage devices particularly rechargeable secondary lithium batteries or lithium-ion batteries (LIBs) as monitoring sensors at the sub-cell level. The present invention includes semiconductor materials compositions fabricated from silicon-based, gallium-based, germanium-based, or a variety of other semiconductor materials as well as implementation methods related thereto. The aforementioned system can be embedded in the structure of negative and positive electrodes, at the interface of electrodes and electrolyte and/or at the interface of electrodes and current collector. The use of semiconductor materials proposed in this invention results in more accurate performance assessment, improved battery state of health monitoring, enhanced battery safety, and extended battery life.

This application claims the benefit under 35 U.S.C.119(e) of U.S. provisional application Ser. No. 63/266,322, filed Dec. 31, 2021.

### FIELD OF THE INVENTION

The battery industry needs rapid, more accurate, and low-cost technology to improve assessing the condition of advanced batteries. The present invention relates to semiconductor materials for use in rechargeable energy storage devices particularly rechargeable secondary lithium batteries, or lithium-ion batteries (LIBs) for monitoring one or more operating parameters.

### BACKGROUND

An electrochemical system either draws electrical energy from chemical processes or uses electrical energy to aid chemical reactions. An electrochemical system usually consists of a cathode, an anode, and an electrolyte, and it is generally complicated with numerous heterogeneous subsystems and scales ranging from nanometers to meters. Fuel cells, batteries, and electroplating systems are examples of these systems.

On-board characterization of electrochemical systems is desirable in many applications, including real-time evaluation of in-flight batteries on a satellite or aviation vehicle and dynamic diagnostics of batteries for electric and hybrid-electric vehicles. The efficiency of batteries in many battery-powered devices may be substantially improved by sophisticated control of the electrochemical energy storage system. A good diagnostic of the battery conditions at the sub-cell level allows for more accurate and efficient management.

In general, a battery's state of health refers to how well a battery performs compared to its initial state. Performance loss due to aging processes or at the battery's end-of-life is indicated by changes in the form of health from the original condition. Battery usage history is combined with physical measurements like electrical current and voltage and operating temperature to predict the battery's SOH and the remaining usage life.

Battery life is frequently a deciding issue in the marketplace, particularly for commercial, military, and aerospace applications. In many aerospace devices, such as satellites, battery life is typically the limiting issue. For instance, lithium-ion batteries have unfortunately caused fires in automobiles, laptops, mobile gadgets, and aeroplanes. As a result, dynamically monitoring the battery status is necessary for performance and functional safety.

There are several existing methods and systems for calculating SOH, SOC, and the factors that affect lithium-ion battery health. However, they all have limitations. Traditional reference electrodes are frequently put between the positive and negative electrodes, and their size is maintained small to avoid the “shielding effect” that alters the current flow between the two electrodes. On the other hand, a very small electrode area might result in a high polarization resistance, which can lead to inaccurate potential measurements. Other traditional approaches include surrounding the battery with a reference electrode that is outside of the direct current path between the positive and negative electrodes. The method monitors the potential of electrode edges, which seldom represents the real potential of the electrode, which is one of the system's disadvantages. At large current densities, this distortion becomes even more pronounced. Zhou and Notten investigate the “development of dependable lithium microference electrodes for long-term in situ investigations of lithium-based battery systems.” The use of micrometer-scale wire as a lithium reference electrode is described in J. Electrochem. Soc. 151 (12) (2004) A2173-A2179. Between the positive and negative electrodes, a micrometer-sized wire is sandwiched. This enables a relatively short distance between the target electrodes, reducing IR drop while avoiding considerable current route distortion due to the shielding effect. When the shielding effect grows more obvious, however, its usage at high rates becomes dubious. Furthermore, micrometer-sized reference electrodes may be problematic to use.

Timmons and Verbrugge describe the use of a cluster or array of reference electrode materials to monitor the state of charge of the positive and negative electrodes in a lithium-ion battery in U.S. Patent App. Pub. No. 2011/0250478. On a shared substrate, an array of lithium-containing reference electrode materials is arranged. A very tiny quantity of each of the reference electrode materials can be used. The potential drifts are measured using a variety of reference electrode materials. Fulop et al. describe the use of lithium, lithium titanium oxide, and lithium iron phosphate as reference electrodes for battery state of charge and health monitoring in U.S. Pat. No. 8,163,410. The reference electrodes might be found on the surface of the container or on the battery's endcap. A wire format reference electrode is placed between the layers or at the edge of the electrode stack.

In U.S. Pat. No. 9,379,418, Wang et al. disclose the use of electrode reference fabricated from lithium metal, lithiated carbon, or a variety of other lithium-containing electrode materials at the cell level to show the voltages of the anode and cathode. A porous current collector enables reference lithium ions to permeate from the reference electrode to the cathode or anode, allowing voltage monitoring during real lithium-ion battery operation.

For today's advanced batteries, a realistic strategy is required to improve battery diagnosis and management systems. Improving battery monitoring, boosting battery safety, better knowledge of battery aging diagnosis, and prolonging battery life are all apparent advantages.

Battery health and life information and battery safety are both commercially important in the marketplace. In order to ease battery state of charge and state of health monitoring, a better battery structure and semiconductor chip sensor designed to measure the potentials of the positive and negative electrodes are needed.

### SUMMARY OF THE INVENTION

The present invention addresses the aforementioned needs in the advanced batteries, which will now be summarized and described in detail below.

The present invention includes materials, components, and methods including semiconductor materials for use as a sensor embedded on LIB electrodes comprising such semiconductor materials, as well as monitoring methods related thereto. The current invention includes all types of chemistries and designs of advanced batteries such as a lithium-ion battery for on-board and at the sub-cell level monitoring, enabling precise electrode health and safety assessment during system operation. The innovation is related explicitly to real-time State-of-Health (SOH) and State-of-Charge (SOC) measurements in advanced batteries utilizing a new technology with semiconductor materials. The said semiconductor materials may include silicon- based, gallium-based and germanium-based semiconductors disposed between the electrodes' layers or on electrodes and electrolyte interface and/or electrodes and current collector interface. The present invention includes semiconductor materials and methods of manufacturing related to semiconductor materials embodiment processing, including simple coating using ceramic paste, electrochemical deposition (ECD), 3D printing or chemical vapour deposition (CVD) of semiconductor materials on LIB electrodes active materials. The present invention also relates to LIB materials including binders, electrolytes, electrolyte additives, and solid electrolyte interfaces (SEI) suitable for use in LIB electrodes comprising semiconductor materials and the cathode and anode active materials, as well as components, devices, and methods of manufacturing related thereto.

More particularly, the present invention includes novel and cost-effective methods for high-resolution monitoring by using semiconductor materials in LIB components and devices, particularly LIB electrodes. Furthermore, the present invention allows for highly controllable processes for embedding semiconductor materials on the surface or between the layers of electrodes. These high-quality semiconductor materials provide consistency and predictability of battery system performance and allow for control over changes to these materials and battery devices throughout the multiple charge cycles and various conditions to which they are subjected. The present invention deploys a new system to monitor the anode and cathode of advanced batteries, including LIB. This innovation helps better measure the SOH and SOC of anode and cathode separately instead of SOH and SOC of each cell or module of advanced batteries.

This invention aims to use a semiconductor material on the cathode and anode for monitoring the behavior of each of them during the cycle life of the battery.

The semiconductor behavior can be observed by changing the number of ions on the cathode and anode during the charge and discharge cycles.

The present invention includes methods for directly depositing discrete semiconductor materials comprising semiconductor materials onto electrode as a substrate via electrochemical deposition, chemical vapour deposition or 3D printing methods as well as compositions, devices and components related thereto. In preferred embodiments, semiconductor materials are deposited directly onto one or both electrode structures and/or surfaces to form monitor sensors at the sub-cell level. In one example embodiment, semiconductor materials are 3D printed on the electrodes' surface to form monitoring sensors. This approach allows for precise structure, composition and dimensions production and improved control of processing of semiconductor material suitable for using in LIBs. Furthermore, this approach allows for improved adhesion between semiconductor materials and the electrodes.

In conventional LIB, the cathode consists of different metals such as lithium, cobalt, nickel, and others coated on aluminum foil. Moreover, the anode is carbon-coated on a copper thin film. In the charging cycle, the positively charged intercalated lithium ions are dissolved into the electrolyte solution. These ions travel over to the anode, where they are intercalated within the anode. While, during discharging, the lithium ions are de-intercalated from the anode and travel back through the electrolyte to the cathode.

Semiconductor materials have a wide range of bandgaps that the number of ions on their structure can affect their bandgap and electrical, optical, and chemical properties. By changing the number of ions on the cathode and anode in discharging and charging cycles, the physical properties of the semiconductor can be changed. Monitoring these physical changes provide information about the number of ions on the cathode and anode in each cycle.

By calibration of the number of ions and behavior of semiconductors, it is possible to measure the health and lifetime of the cathode and anode. Moreover, by analyzing the data for each type of cathode and anode with different chemistries, the charge and discharge behavior of cathode and anode can be estimated in different conditions and usage patterns.

These data from cathode and anode will be provided to the consumer for knowing the best usage pattern of their batteries or helping them to choose the best chemistry of lithium-ion batteries according to their usage pattern.

According to one aspect of the invention there is provided a battery comprising:

a plurality of cells, each cell comprising an electrolyte operatively connected between a pair of electrodes in which the pair of electrodes comprises an anode and a cathode;

a plurality of semiconductor bodies in operative connection with respective ones of the electrodes, each semiconductor body comprising a semiconductor material having material properties changeable with changing operating parameters of the respective electrode; and

a monitoring arrangement in operative communication with the semiconductor bodies so as to be arranged to sense said material properties of the semiconductor bodies.

Direct measurements of battery electrodes (cathode and anode) condition can substantially improve battery safety while also improving the accuracy and reliability of battery management systems.

The semiconductor bodies may be in operative connection with at least some of the anodes, in operative connection with at least some of the cathodes, in operative connection with some anodes and some cathodes, or more preferably each anode and each cathode of the battery includes one of the semiconductor bodies in operative connection therewith.

The semiconductor bodies are arranged such that material properties of the semiconductor bodies are changeable in response to changes to a number of ions on the electrodes as the electrodes are operated between full charge and discharge states of the battery.

The semiconductor bodies may be associated with the electrodes so that (i) some of the semiconductor bodies are embedded within the respective electrodes, (ii) some of the semiconductor bodies are located at an electrode interfacing surface of the respective electrode in which the electrolyte interfacing surface comprises a boundary of the electrode directly adjacent to the electrolyte, (iii) some of the semiconductor bodies are located at a current collector junction of the respective electrode in which the current collector junction comprises a boundary of the electrode directly adjacent to a current collector of the electrode, or any combination of (i) to (iii).

The semiconductor material of the semiconductor bodies preferably comprises one or more selected from the group consisting of silicon-based, gallium-based, germanium-based and semiconductor transition metal dichalcogenides (TMDs).

The semiconductor bodies are applicable to electrodes in operative connection with an electrolyte comprising either a liquid electrolyte, a semi-solid electrolyte, or a solid electrolyte.

According to another aspect of the present invention there is provided a method of monitoring a battery of the type described above in which the method comprises determining at least one operating condition of the battery by monitoring said material properties of the semiconductor bodies.

The method may further comprise sensing said material properties of the semiconductor bodies externally in real-time during charging, discharging and resting time of the battery.

The method may further comprise determining a state of health and a state of charge of each cell of the battery by: (i) determining an initial storage capacity of each electrode by sensing said material properties of the semiconductor bodies in an initial fully charged state and an initial fully discharged state of the battery in which the sensed material properties are indicative of a number of ions on both the anode and the cathode of each cell; and (ii) determining a subsequent storage capacity of each electrode by sensing said material properties of the semiconductor bodies in a subsequent fully charged state and a subsequent fully discharged state of the battery in which the sensed material properties are indicative of a number of ions on both the anode and the cathode of each cell.

The method may further comprise diagnosing internal battery degradation by sensing said material properties of the semiconductor bodies, said internal battery degradation including any one of formation of solid electrolyte interface (EIS), battery overcharge, and battery over-discharge.

According to another aspect of the present invention there is provided a method of manufacturing a battery described above, or a method of manufacturing an electrode for the battery described above, the method comprising incorporating the semiconductor bodies into the electrodes respectively during manufacturing of the electrodes.

The method may further comprise (i) placing the semiconductor bodies on the respective electrodes by coating the semiconductor material onto the electrodes, (ii) placing the semiconductor bodies on the respective electrodes as a ceramic paste during assembly of the cells, or (iii) placing the semiconductor bodies on the respective electrodes using 3D printing.

### BRIEF DESCRIPTION OF THE DRAWINGS

The accompanying drawings, which are incorporated herein and form a part of the specification, depict the present invention and, in conjunction with the description, serve to further explain the principles of the invention and enable a person skilled in the relevant art to make and use the invention.

FIG. 1 is a schematic representation of a lithium-ion cell with different components: aluminum current collector, cathode, semiconductor material, anode, electrolyte, separator, and copper current collector.

FIG. 2 is a schematic representation of the band gap between the valence band and the conduction band of metal, semiconductor and insulator materials, in which the Fermi level is the name given to the highest energy inhabited electron orbital at absolute zero.

FIG. 3 is a schematic representation of the semiconductor bandgap with an electron-hole pair in which the full valence band containing electrons and the empty conduction band are seen in a semiconductor's band diagram, and in which the space between these two places is known as the band gap, wherein at room temperature thermal stimulation can cause some electrons to move from the valence to the conduction band.

FIG. 4 is a schematic representation the conduction band and valence band structure of an n-type semiconductor in which electrons are the “majority carriers” for current flow in an n-type semiconductor, and electrons can be elevated to the conduction band and flow through the material.

FIG. 5 is a schematic representation of the conduction band and valence band structure of a p-type semiconductor in which electrons are thought to be mobile because they may travel between the holes, in which the holes are regarded as the “majority carriers” for current flow in a p-type semiconductor.

FIG. 6 is a schematic representation of the different locations for placement of the semiconductor materials including (i) onto the electrodes' structure, (ii) at the interface of the electrode and electrolyte, and (iii) at the interface of the electrodes and current collector.

FIG. 7A is a schematic representation of the movement of Li+ions during the charge cycles of a LIB.

FIG. 7B is a schematic representation of the movement of Li+ions during the discharge cycles of a LIB.

FIG. 8 is a schematic representation of a battery comprising multiple cells including semiconductor bodies incorporated into the electrodes according to the present invention.

In the drawings like characters of reference indicate corresponding parts in the different figures.

### DETAILED DESCRIPTION

The approach described herein pertains to all advanced batteries, including batteries based on lithium as the most widely available category due to their advantages such as their higher energy density compared to other commercial batteries for the on-board lithium-ion battery electrodes monitoring. A semiconductor material is used to determine the cathode and the anode SOH and SOC, and distinguishes between various defects that may develop inside the battery at the sub-cell level. The number of ions on electrodes during the charge, discharge, and the rest time of the battery can be monitored by the changing physical properties of the semiconductor materials, which results from the semiconductor bandgap change.

In general, the quantity of active ions moving between the anode and the cathode determines the battery capacity. Ions leave the cathode and enter the anode when the battery is charged for the first time. Because some lithium is generally lost to form a solid-state electrolyte interface on the anode surface after all detachable ions leave the cathode, only a portion of that ions are active in the anode. The number of active ions in subsequent battery cycles will be less than the cathode's storage capacity and the anode. As a result, the capacity of a lithium battery is generally equal to the number of active ions. Corrosion of these active ions causes capacity reduction throughout the battery's lifetime.

In an exemplary embodiment of the invention, a new sensing method, prognostic technique, and system can be utilized that monitor the health of advanced batteries at the sub-cell level. The method can be used to scan and monitor the health of batteries independent of their charge status, making it helpful while charging, discharging, or periods of rest (e.g., no current flow). This innovation is independent of the chemistry and geometry of advanced batteries and can be set up on cylindrical, prismatic, and pouch cells.

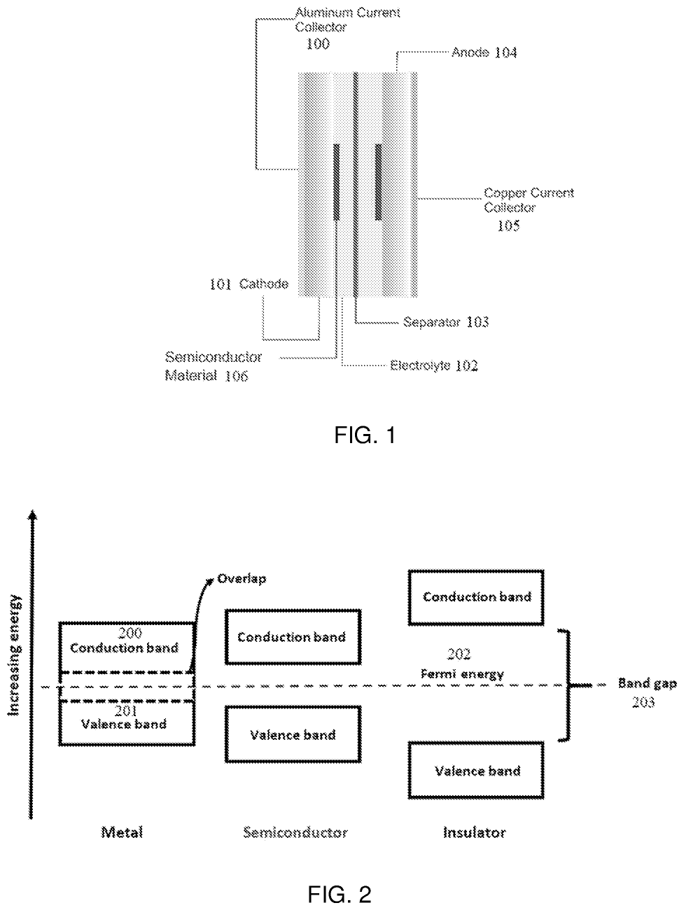

FIG. 1 is the schematic of one cell of the LIB, including:

100: Aluminum current collector: aluminium foil is extensively used as a current collector material for cathode electrodes in commercial LIB, as it meets the majority of practical characteristics, such as conductivity, malleability, density, material cost, and, most importantly, chemical and electrochemical stability.

101 Cathode: lithium-based layered metal oxide acts as a cathode 102 Electrolyte: a liquid organic solvent containing lithium salt that allows ions (ionic components) to flow instead of electrons.

103 Separator: an insulator material is electrolyte-permeable.

104 Anode: based on graphitic carbon.

105 Copper current collector: the most widely utilised anode current collector for lithium ion batteries, because of its high stability at low potential, and

106 Semiconductor body formed of semiconductor material: New Semiconductor material compositions with high chemical and electrochemical stability as a sensor for state of health and state of charge monitoring at the sub-cell level.

The invention system is the new structure and component of the semiconductor body 106 formed of semiconductor material embedded at the interface of electrodes and electrolyte and/or interface of electrodes and current collectors, or onto the layers of electrodes. The semiconductor sensor does not affect the performance and parameters of the lithium-ion battery, and just enables new monitoring and sensing layer at the particle scale.

As shown schematically in FIG. 8, an overall battery 10 according to the present invention includes a positive terminal 12 and a negative terminal 14 which are operatively connected to individual cells 16 of the battery. Each of the individual cells 16 may arranged according to the battery cell shown in FIG. 1 such that each cell includes: (i) a cathode 101, (ii) an anode 104, (iii) an electrolyte 102 operatively connected between the cathode 101 and the anode 104, (iv) a first current collector 100 conductively connected to the cathode 101 for operative connection to the positive terminal 12 of the battery, (v) a second current collector 105 conductively connected to the anode 104 for operative connection to the negative terminal 14 of the battery, and (vi) a separator 103 within the electrolyte 102 at an intermediate location between the cathode 101 and the anode 104. Each cell 16 of the battery 10 further includes a semiconductor body 106 formed of semiconductor material that is operatively connected to each electrode of the electrode pair comprising the cathode 101 and the anode 104. The semiconductor bodies 106 are located within the cells so that the bodies are in operative connection with some or all of the anodes and/or some or all of the cathodes of the battery.

The semiconductor bodies may be placed such that: (i) in some or all of the electrodes, the semiconductor bodies 106 can be embedded within the respective electrodes so as to be fully surrounded by the material of the electrode; (ii) in some or all of the electrodes, the semiconductor bodies 106 are located at an electrode interfacing surface of the respective electrode in which the electrolyte interfacing surface comprises a boundary of the electrode directly adjacent to the electrolyte; (iii) in some or all of the electrodes, the semiconductor bodies 106 are located at a current collector junction of the respective electrode in which the current collector junction comprises a boundary of the electrode directly adjacent to a current collector of the electrode; or (vi) any combination of the arrangements described in (i), (ii) or (iii).

The battery 10 in this instance includes an associated monitoring arrangement 18 which may comprise a suitable monitoring circuit including a memory storing programming instructions thereon and a processor for executing the programming instructions to execute the various functions described herein. The monitoring arrangement is in operative communication with the semiconductor bodies by direct connection or remote communication in a manner which enables sensing of the material properties of the semiconductor bodies 106.

A group of crystalline solids known as semiconductors have a conductivity between conductors (often metals) and non-conductors or insulators (such as most ceramics). Semiconductors can be made of compounds like gallium arsenide, cadmium selenide, or pure elements like silicon or germanium. Diodes, transistors, and integrated circuits are just a few of the electrical devices that use semiconductors in their production. Due to their portability, dependability, energy efficiency, and affordability, these gadgets are widely used. They are discrete components in solid-state lasers, optical sensors, and power devices. They are capable of tolerating a broad range of current and voltage, and more importantly, they are well suited for integration into intricate yet easily fabricated microelectronic circuits.

The range of energy levels in a material known as a band gap cannot support the existence of electrons. Understanding a material's electronic behaviour and determining whether it has a band gap or not, as well as its size, may help us identify electrical insulators, conductors, and semiconductors. FIG. 2 shows the schematic of the bandgap for metals, semiconductors and insulators that is including different parts:

200 Conduction band: When electrons are excited, they can jump up into the conduction band, a band of electron orbitals, from the valence band. The electrons have sufficient energy in these orbitals to pass unimpededly through the substance. Electric current is created by electron motion.

201 Valence band: A group of electron orbitals known as the valence band allows energized electrons to leap into the conduction band. The valence band is the outermost electron orbital that electrons occupy on an atom of a particular chemical.

202 Fermi energy: The maximum energy level an electron may attain at absolute zero is known as the Fermi level. Since electrons remain in the lowest energy state at absolute zero temperature, the Fermi level is the state that lies between the conduction and valence bands.

203 Band gap: The band gap is the amount of energy needed for an electron to escape from its confined state. The electron is stimulated into a free state and may take part in conduction when the band gap energy is reached.

Since there are no band gaps in conductive materials, electrons can travel freely in a continuous, partially filled conduction band. Band gap is narrower in semiconductor materials, and at ambient temperature, there is enough energy available to shift a few electrons from the valence band into the conduction band. A semiconductor material's conductivity rises with increasing temperature. Between the conduction band and the valence band in insulators, there is a significant band gap. Since there is no electron movement, the valence band stays full, which also leaves the conduction band vacant.

The minimum amount of energy needed to move an electron from its bound state into a condition where it may conduct electricity is known as a semiconductor's band gap. A “band diagram” represents the band structure of a semiconductor, which displays the energy of the electrons on the y-axis. The energy difference between the valence band and conduction band is known as the band gap (EG). The band gap is the lowest energy change necessary to excite the electron and enable it to take part in conduction. The electron is free to roam about the semiconductor and take part in conduction once it has been stimulated into the conduction band. An extra conduction process will be possible, though, if an electron is excited into the conduction band. An open area for an electron remains after an electron is excited to the conduction band. This open region can be filled by an electron from an atom nearby. This electron moves and creates a new space. A positively charged particle moving continuously through the crystal structure can be used to represent the motion of an electron's “hole,” which is the empty space for an electron. As a result, when an electron is excited into the conduction band, a hole is also created in the valence band in addition to the electron. As a result, both the electron and the hole are considered “carriers” and can participate in conduction.

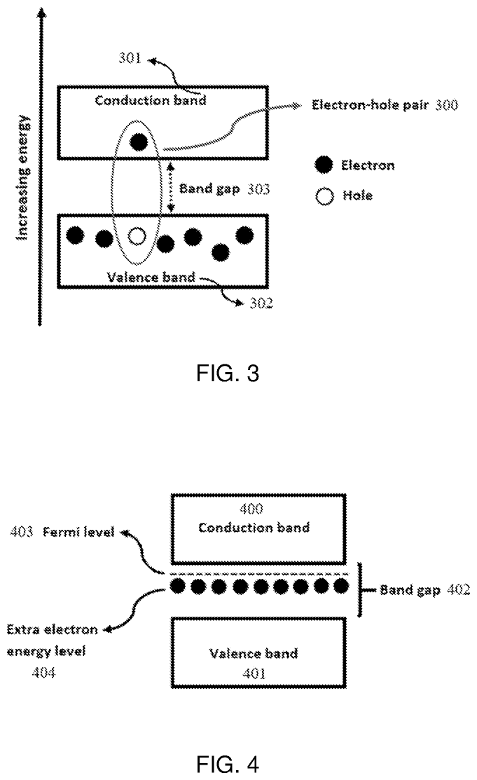

FIG. 3 illustrates the schematic of the electron-hole pair in semiconductor materials. Excitation of electrons from the valence band to the conduction band creates free charge carriers in semiconductors. This excitation formed an electron-hole pair 300 by leaving a hole in the valence band that behaves as a positive charge.

Small amounts of impurities are added to pure semiconductors in a process known as doping, and extra electrons or holes can be introduced into the material by substituting an impurity atom—an atom with a slightly different valence number—into the crystal lattice, leading to significant changes in the conductivity of the material. For instance, the electrical conductivity of silicon may be multiplied by 1,000 by adding around 10 dopant boron atoms per million silicon atoms.

Donor impurities are impurities that have an additional electron, and n-type semiconductors are doped semiconductors because their principal charge carriers (electrons) are negative.

FIG. 4 shows an n-type semiconductor. By adding more donor impurities, we can create an impurity band, a new energy band created by semiconductor doping, as shown in 404. The Fermi level is now between 404 and the conduction band. Numerous impurity electrons are thermally stimulated into the conduction band at normal temperature and contribute to conductivity. As vacancies are generated in the impurity band, conductivity can also occur there.

Impurity atoms, which generally have one less valence electron than semiconductor atoms, can also be used for doping. Because holes are the main positive charge carriers, this impurity is known as an acceptor impurity, and the doped semiconductor is referred to as a p-type semiconductor. In the band gap just above the valence band, an empty electron state is produced if a hole is seen as a positive particle weakly linked to the impurity site. A mobile hole is produced in the valence band when this state is occupied by an electron that has been thermally stimulated from the valence band. impurity band can be produced by including more acceptor impurities.

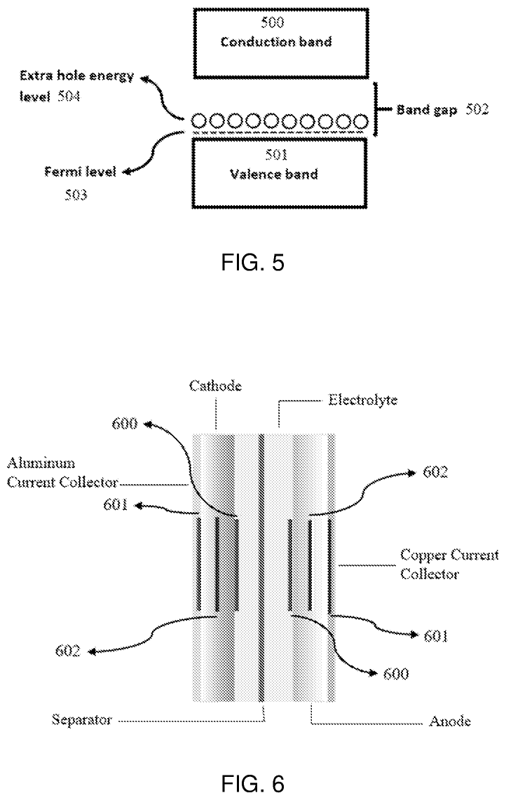

FIG. 5 shows formation of an impurity band in a p-type semiconductor and 500 is the mobile hole as the majority carriers.

According to the above information about a behaviour of semiconductor's bandgap, the number of ions on their structure, changing their substrate properties, and changing the temperature and pressure can affect their bandgap. Bandgap changing can alter the electrical, optical, and chemical properties of the semiconductor. Tracking all these alternations provide valuable and precise information about the situation. Therefore, using the semiconductor material on the cathode and anode in the LIBs would be the most accurate technique for monitoring the condition of the battery.

With different methods including chemical vapour deposition (CVD) or 3D printing, the semiconductor materials can be simultaneously formed and deposited on/into the electrodes as a substrate.

FIG. 6 shows different positions for a monitoring semiconductor material sensor. The semiconductor materials can be formed on electrodes' surface 600 and 601 or in the layer structure of electrodes 602. Therefor, the semiconductor materials can be embedded on the surface of the electrodes on the electrolyte site or current collector site.

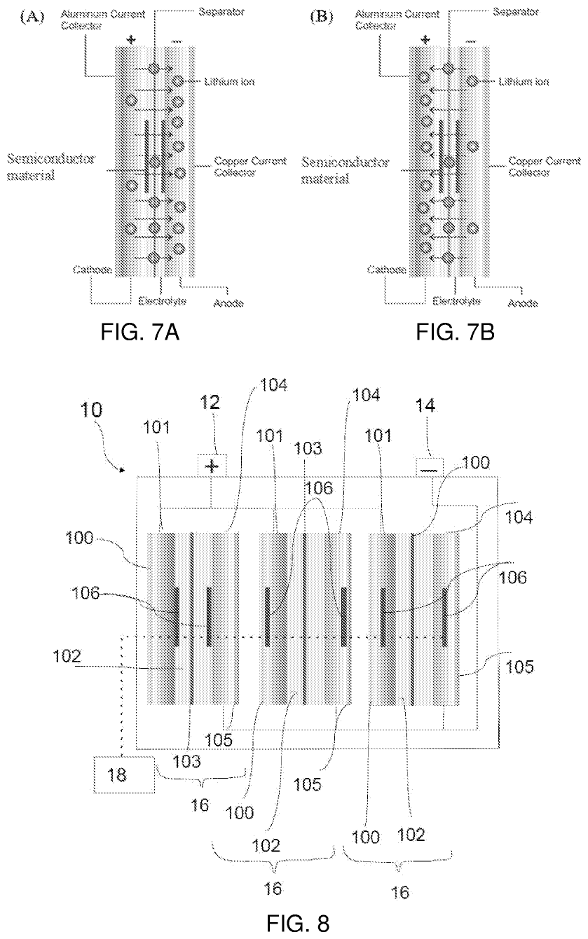

The lithium ions move in the electrolyte from the cathode to the anode in the charging cycle (FIG. 7A). In the first charging cycle of LIB, the maximum number of ions can be intercalated on the anode in full charge. However, after the battery cycles, due to the degradation in the anode and chemical reaction at the particle scales, the capacity of the anode will decrease for storing lithium ions therefore lower lithium ions can sit on the anode during the charging cycle and in the full charge state. Changing the number of ions in the anode structure affects the properties of the semiconductor materials. Monitoring and analyzing these changes provide additional and more accurate information about the health of the anode.

On the other hand, the same situation will happen for the cathode during the discharging cycle. In the first discharging cycle of LIB, all lithium ions can leave the anode and sit on the cathode during the discharging (FIG. 7B). Still, some ions will be trapped in the anode or lose their ability to sit in the cathode as the battery cycles, hence the number of ions will decrease, and the embedded semiconductor materials can monitor this change.

Moreover, the proposed invention enables monitoring the performance of the cathode and the anode in the resting time of the battery. The number of ions that will move in the battery per second can be observed and estimated.

One of the most critical aspects of the advanced batteries is their safety which can make a huge cost for battery makers and automotive OEMs. This innovative semiconductor materials can improve the safety of advanced batteries and alert for any failure at the sub-cell level before it happens. The invention enables detecting any minor changes including local temperature, formation of the solid electrolyte interface (SEI) layers, dendrite structure and microcrack at the sub-cell level.

The system and method presented in this invention are valid for the battery's entire lifecycle including the end of life applications, such as repurposed batteries for stationary applications or for recycling. To this end, with this system, exact information will be available about all cathode and anode for all cells in the battery pack; thus, by knowing the health of the battery in detail, the second life is more reliable to determine the most efficient and cost-effective application according to the battery's status. For instance, among various types of LIBs, Lithium Iron Phosphate (LFP) is a prominent battery chemistry in the future because of its lower cost than the cathode chemistry with cobalt and nickel, higher tolerance to degradation due to its solidity of structure, and thermal tolerance, which improves safety. LFP battery is not suitable for recycling because the cost of recycling is more than raw materials. Therefore, a reliable second lifetime is critical in LFP batteries. This innovation can provide clear and precise information about the health of each cell component at the first end of life. This valuable information can help customers decide easier, with more trust and security and lower cost. Secondly, according to the high demand and growth of lithium-ion batteries, forecasting shows around 400,000 tonnes of lithium-ion batteries will be available for recycling in 2025. This innovative method and system help reduce the time, difficulty, and price of recycling for all recycling methods such as pyrometallurgy, hydrometallurgy, and direct recycling. Moreover, the unknown situation of battery cells is a major safety problem in recycling. The valuable information from all cells in the cathode and anode scale solve the safety problem during recycling, specifically for the direct recycling method.

As described herein, a system and method are provided for real-time sensing and monitoring of advanced rechargeable batteries by adding semiconductor materials at the sub-cell level, i.e., anode and cathode. The system includes new anode and cathode structures where the semiconductor materials are embedded in the structure of the electrodes or on the respective electrode's surface interfacing the electrolyte and/or electrode - current collector junction. The semiconductor materials include new semiconductor material compositions and structures with a wide range of bandgaps that are flexible and changeable by environmental changes. The new method for the above system is to sense, monitor, and analyze the changeable semiconductor properties.

The plurality of discrete semiconductor materials may comprise one or more selected from the group consisting of silicon-based, gallium-based, germanium-based and semiconductor transition metal dichalcogenides (TMDs).

The dimensions of semiconductor materials as monitoring sensors are flexible and changeable without affecting their performance owing to the geometry of LIB including pouch, cylindrical and prismatic, as well as the size of the cell and electrodes.

The semiconductor materials are applicable on different chemistries of cells including various cathode and anode chemistries, liquid, quasi-solid and solid-state electrolyte.

The semiconductor materials placed on the electrodes can be generalized for all types of advanced batteries with different chemistries such as lithium-ion, sodium-ion, lithium-air, lithium-sulfur as the leading advanced batteries.

The number of ions on the electrodes in full charge and discharge states which affect the semiconductor materials' properties can be monitored. The number of ions on the cathode and anode in the battery's full charge and discharge states will change the physical properties of the semiconductor materials embedded on the electrodes/electrolyte surface or electrodes/current collector surface or in the electrodes' structure. The bandgap of the semiconductor materials will be changed when the number of ions on the positive and negative electrodes changes during their lifecycle. Any changes in the semiconductor bandgap appear as changing on the optical and electrical properties. The electrical change can be monitored externally in real-time during the charging, discharging, or resting time of the battery.

The invention deploys new semiconductor material compositions for the system above, wherein different compositions are designed to be compatible with LIB's envoironment including temperature and electrochemical reactions with high corrosion resistance and stability. The semiconductor materials are usually based on silicon material components due to the lower cost, higher thermal stability, and lower leakage current. Although in this innovative monitoring and sensing system, there is no limitation for the semiconductor materials, and these sensors can be germanium, gallium, gallium arsenide and among other semiconductor materials.

The state of health (SOH) and state of charge (SOC) of each positive and negative electrode on different cells independent from chemistry and geometry can be determined for the first time by the monitoring of the number of ions on electrodes with the semiconductor materials. This includes measuring and calibrating the number of ions on both positive and negative electrodes with the semiconductor materials in the first fully charged and discharged states of battery separately shows the storage capacity of each electrode with high resolution and in particle scale. Subsequently the response of the semiconductor materials at the full charge and discharge of the battery after each cycle is monitored. The response of silicon-based semiconductor materials is correlated to the number of ions and storage capacity of electrodes after charge and discharge cycles. Analyzing the response of silicon-based semiconductor materials in each cycle provides information about the direct SOH and SOC of the cathode and anode.

The addition of the semiconductor materials to be placed on the electrodes, can be implemented in different manufacturing steps of battery with different techniques. In one example, a simple coating method places semiconductor materials onto the layers of electrodes for all types of batteries such as conventional lithium-ion, solid-state, or quasi-solid in the coating and drying step of manufacturing. Alternatively, the semiconductor materials can be placed on the surface of the electrodes during the cell assembly manufacturing step by the ceramic paste. In another instance, a new approach will be deployed to implement semiconductor materials on the surface of the electrode using 3D printing to integrate additives into the printing process and to provide the ability to print embedded semiconductor materials into the batteries with lower cost and more flexibility in the shape and dimensions.

The SOH and SOC of the battery at the sub-cell level can be monitored in real-time, enabling enhanced assessment onboard the vehicle and without the need to be removed from the vehicle, any lab tests or external tests that require to remove the battery or extra equipment.

The method is able to diagnose internal battery degradation such as the formation of solid electrolyte interface (EIS), battery overcharge, and battery over-discharge at the sub-cell level due to the misuse with no extra equipment or lab testing and changing in the battery pack.

The safety can increase by sub-cell level monitoring, such that it is possible to alert any failure before it happens.

Since various modifications can be made in the invention as herein above described, and many apparently widely different embodiments of same made, it is intended that all matter contained in the accompanying specification shall be interpreted as illustrative only and not in a limiting sense.

1. A battery comprising:
a plurality of cells, each cell comprising an electrolyte operatively connected between a pair of electrodes in which the pair of electrodes comprises an anode and a cathode;
a plurality of semiconductor bodies in operative connection with respective ones of the electrodes, each semiconductor body comprising a semiconductor material having material properties changeable with changing operating parameters of the respective electrode; and
a monitoring arrangement in operative communication with the semiconductor bodies so as to be arranged to sense said material properties of the semiconductor bodies.

2. The battery according to claim 1 wherein the semiconductor bodies are in operative connection with at least some of the anodes.

3. The battery according to claim 1 wherein the semiconductor bodies are in operative connection with at least some of the cathodes.

4. The battery according to claim 1 wherein each anode and each cathode of the battery includes one of the semiconductor bodies in operative connection therewith.

5. The battery according to claim 1 wherein said material properties of the semiconductor bodies are changeable in response to changes to a number of ions on the electrodes as the electrodes are operated between full charge and discharge states of the battery.

6. The battery according to claim 1 wherein at least some of the semiconductor bodies are embedded within the respective electrodes.

7. The battery according to claim 1 wherein at least some of the semiconductor bodies are located at an electrode interfacing surface of the respective electrode in which the electrolyte interfacing surface comprises a boundary of the electrode directly adjacent to the electrolyte.

8. The battery according to claim 1 wherein at least some of the semiconductor bodies are located at a current collector junction of the respective electrode in which the current collector junction comprises a boundary of the electrode directly adjacent to a current collector of the electrode.

9. The battery according to claim 1 wherein said semiconductor material of the semiconductor bodies comprises one or more selected from the group consisting of silicon-based, gallium-based, germanium-based and semiconductor transition metal dichalcogenides (TMDs).

10. The battery according to claim 1 wherein the electrolyte comprises a liquid electrolyte.

11. The battery according to claim 1 wherein the electrolyte comprises a semi-solid electrolyte.

12. The battery according to claim 1 wherein the electrolyte comprises a solid electrolyte.

13. A method of monitoring a battery according to claim 1 comprising determining at least one operating condition of the battery by monitoring said material properties of the semiconductor bodies.

14. The method according to claim 13 further comprising sensing said material properties of the semiconductor bodies externally in real-time during charging, discharging and resting time of the battery.

15. The method according to claim 13 further comprising determining a state of health and a state of charge of each cell of the battery by:
determining an initial storage capacity of each electrode by sensing said material properties of the semiconductor bodies in an initial fully charged state and an initial fully discharged state of the battery in which the sensed material properties are indicative of a number of ions on both the anode and the cathode of each cell; and
determining a subsequent storage capacity of each electrode by sensing said material properties of the semiconductor bodies in a subsequent fully charged state and a subsequent fully discharged state of the battery in which the sensed material properties are indicative of a number of ions on both the anode and the cathode of each cell.

16. The method according to claim 13 further comprising diagnosing internal battery degradation by sensing said material properties of the semiconductor bodies, said internal battery degradation including any one of formation of solid electrolyte interface (EIS), battery overcharge, and battery over-discharge.

17. A method of manufacturing a battery according to claim 1 comprising:
incorporating the semiconductor bodies into the electrodes respectively during manufacturing of the electrodes.

18. The method according to claim 17 further comprising placing the semiconductor bodies on the respective electrodes by coating the semiconductor material onto the electrodes.

19. The method according to claim 17 further comprising placing the semiconductor bodies on the respective electrodes as a ceramic paste during assembly of the cells.

20. The method according to claim 17 further comprising placing the semiconductor bodies on the respective electrodes using 3D printing.
